(19) United States
(12) Patent Application Publication
(10) Pub. No.: US 2025/0095957 A1
(43) Pub. Date: Mar. 20, 2025

(54) ION PRODUCTION SYSTEM WITH A MASS RESOLVING APERTURE HAVING A SCATTER RECESS

(71) Applicant: SHINE Technologies, LLC, Janesville, WI (US)

(72) Inventors: Ross Radel, Brooklyn, WI (US); Sarko Cherekdjian, Campbell, CA (US)

(21) Appl. No.: 18/884,519

(22) Filed: Sep. 13, 2024

Related U.S. Application Data
(60) Provisional application No. 63/538,389, filed on Sep. 14, 2023.

(51) Int. Cl. H01J 37/304; H01J 37/317

(52) U.S. Cl. CPC H01J 37/304; H01J 37/317

(57) ABSTRACT

A mass resolving aperture comprising an aperture body, an open aperture extending through the aperture body from an entry side to an exit side and a scatter recess extending into the entry side of the aperture body and terminating at a recess floor positioned between the entry side and the exit side.

### CROSS-REFERENCE TO RELATED APPLICATION

This application claims the benefit of U.S. Provisional Application No. 63/538,389, filed Sep. 14, 2023, which is incorporated herein by reference in its entirety.

### TECHNOLOGY

The present disclosure relates generally to systems and methods of ion beam generation and use.

### BACKGROUND

Previous technologies that involve ion beams are typically intended to provide high-energy collisions between the ion beam and a substrate material, in order to create changes to the substrate material. Ion beam implantation is often used is semiconductor and material modification applications. Such systems and methods do not provide for high-efficiency collection of the ions by themselves (i.e., turning an ion beam back into a solid). One goal of the present application is collection of the ions of the ion beam as a constituted material which can be collected, stored, transported, used, etc., for example in health care applications.

### SUMMARY

According to a first aspect of the present disclosure, a mass resolving aperture includes an aperture body, an open aperture extending through the aperture body from an entry side to an exit side; and a scatter recess extending into the entry side of the aperture body and terminating at a recess floor positioned between the entry side and the exit side.

A second aspect includes the mass resolving aperture of the first aspect, wherein the exit side of the aperture body comprises an exit face and a capture face; and the open aperture extends through the aperture body from the entry side to the exit face of the exit side.

A third aspect includes the mass resolving aperture of the second aspect, wherein the exit face is closer to the entry side of the aperture body, along a beam propagation direction, than the capture face.

A fourth aspect includes the mass resolving aperture of the second or third aspects, wherein the aperture body comprises a protrusion wall extending from the exit face to the capture face.

A fifth aspect includes the mass resolving aperture of the fourth aspect, wherein the protrusion wall extends along a protrusion plane, wherein, at the entry side, the protrusion plane is located between the open aperture and the scatter recess.

A sixth aspect includes the mass resolving aperture of any of the second through fifth aspects, wherein the exit face is closer to the entry side of the aperture body, along a beam propagation direction, than the recess floor of the scatter recess.

A seventh aspect includes the mass resolving aperture of any of the previous aspects, wherein the scatter recess comprises a recess opening at an entry face of the entry side of the aperture body; the open aperture comprises an entry opening at the entry face of the aperture body; and the recess opening comprises a larger cross-sectional area than the entry opening.

An eighth aspect includes the mass resolving aperture of any of the previous aspects, wherein the scatter recess comprises a recess opening at an entry face of the entry side of the aperture body; the open aperture comprises an entry opening at the entry face of the aperture body; and the recess opening and the entry opening are each adjustable.

A ninth aspect includes the mass resolving aperture of any of the previous aspects, wherein at least a portion of the aperture body comprises a carbon material.

A tenth aspect includes the mass resolving aperture of any of the previous aspects, wherein comprising a carbon insert removably positioned in the open aperture.

An eleventh aspect includes the mass resolving aperture of the tenth aspect, wherein the exit side of the aperture body comprises an exit face and a capture face; the open aperture extends through the aperture body from the entry side to the exit face of the exit side; the aperture body comprises a protrusion wall extending from the exit face to the capture face; the carbon insert comprises a band portion with an insert opening and a barrier portion extending from the band portion; and when the band portion is positioned in the open aperture, the barrier portion extends along the protrusion wall.

According to a twelfth aspect of the present disclosure, an ion production system includes an ion source configured to produce ions; a collection target; an extraction electrode positioned between the ion source and the collection target and configured to accelerate ions, forming an ion beam along a beam pathway; a mass resolving aperture that includes an aperture body; an open aperture extending through the aperture body from an entry side to an exit side; and a scatter recess extending into the entry side of the aperture body and terminating at a recess floor positioned between the entry side and the exit side; and a magnetic analyzer positioned along the beam pathway between the extraction electrode and the mass resolving aperture, wherein the magnetic analyzer is configured to apply a magnetic field to the ion beam thereby spatially separating a target beam portion of the ion beam and a secondary beam portion of the ion beam.

A thirteenth aspect includes the ion production system of the twelfth aspect, wherein the collection target and at least a portion of the mass resolving aperture comprise a carbon material.

A fourteenth aspect includes the ion production system of the twelfth or thirteenth aspect, wherein the collection target comprises a fibrous lattice.

A fifteenth aspect includes the ion production system of the fourteenth aspect, wherein the fibrous lattice is a lattice of carbon fibers.

A sixteenth aspect includes the ion production system of the fourteenth aspect, wherein the fibrous lattice comprises graphite.

A seventeenth aspect includes the ion production system of any of the twelfth through sixteenth aspects, wherein the target beam portion of the ion beam comprises ytterbium-176 and the secondary beam portion of the ion beam comprises one or more other ytterbium isotopes.

An eighteenth aspect includes the ion production system of any of the twelfth through sixteenth aspects, wherein the target beam portion of the ion beam comprises gadolinium-152, gadolinum-155, or gadolinum-160, and the secondary beam portion of the ion beam comprises one or more other gadolinium isotopes.

A nineteenth aspect includes the ion production system of any of the twelfth through sixteenth aspects, wherein the target beam portion of the ion beam comprises tellurium-124, and the secondary beam portion of the ion beam comprises one or more other tellurium isotopes.

A twentieth aspect includes the ion production system of any of the twelfth through nineteenth aspects, wherein the exit side of the aperture body comprises an exit face and a capture face; and the open aperture extends through the aperture body from the entry side to the exit face of the exit side.

A twenty-first aspect includes the ion production system of the twentieth aspect, wherein the exit face is closer to the entry side of the aperture body, along a beam propagation direction, than the capture face.

A twenty-second aspect includes the ion production system of the twentieth aspect or twenty-first aspect, wherein the aperture body comprises a protrusion wall extending from the exit face to the capture face.

A twenty-third aspect includes the ion production system of the twenty-second aspect, wherein the protrusion wall extends along a protrusion plane, wherein, at the entry side, the protrusion plane is located between the open aperture and the scatter recess.

A twenty-fourth aspect includes the ion production system of any of the twentieth through twenty-third aspects, wherein the exit face is closer to the entry side of the aperture body, along a beam propagation direction, than the recess floor of the scatter recess.

A twenty-fifth aspect includes the ion production system of any of the twelfth through twenty-fourth aspects, wherein the scatter recess comprises a recess opening at an entry face of the entry side of the aperture body; the open aperture comprises an entry opening at the entry face of the aperture body; and the recess opening comprises a larger cross-sectional area than the entry opening.

A twenty-sixth aspect includes the ion production system of any of the twelfth through twenty-fifth aspects, wherein the scatter recess comprises a recess opening at an entry face of the entry side of the aperture body; the open aperture comprises an entry opening at the entry face of the aperture body; and the recess opening and the entry opening are each adjustable.

According to a twenty-seventh aspect of the present disclosure, a method includes accelerating ions from an ion source to form an ion beam using an extraction electrode positioned between the ion source and a mass resolving aperture, wherein the ion beam propagates along a beam pathway toward a collection target; applying a magnetic field to the ion beam using a magnetic analyzer positioned along the beam pathway between the extraction electrode and the mass resolving aperture thereby spatially separating a target beam portion of the ion beam and a secondary beam portion of the ion beam; and obstructing the secondary beam portion using the mass resolving aperture, wherein the mass resolving aperture comprises an aperture body; an open aperture extending through the aperture body from an entry side to an exit side; a scatter recess extending into the entry side of the aperture body and terminating at a recess floor positioned between the entry side and the exit side; and wherein at least a portion of the secondary beam portion enters the scatter recess of the mass resolving aperture.

A twenty-eighth aspect includes the method of the twenty-seventh aspect, further including collecting ions of the target beam portion on the collection target after the target beam portion of the ion beam passes through the open aperture of the mass resolving aperture.

A twenty-ninth aspect includes the method of the twenty-eighth aspect, wherein the collection target comprises a lattice of carbon fibers and collecting the target beam portion of the ion beam comprises decelerating ions of the target beam portion by deflecting the ions off a plurality of the carbon fibers of lattice of carbon fibers.

A thirtieth aspect includes the method of the twenty-ninth aspect, further including burning the lattice of carbon fibers to obtain a residue comprising the ions of the target beam portion of the ion beam.

A thirty-first aspect includes the method of any of the twenty-seventh through thirtieth aspects, wherein the collection target and at least a portion of the mass resolving aperture comprise a carbon material.

A thirty-second aspect includes the method of the thirty-first aspect, wherein a portion the ion beam impinges the mass resolving aperture, removing at least some of the carbon material of the mass resolving aperture such that removed carbon material of the mass resolving aperture is collected by the collection target together with the target beam portion of the ion beam.

A thirty-third aspect includes the method of any of the twenty-seventh through thirty-second aspects, wherein the magnetic field spatially separates the target beam portion and the secondary beam portion of the ion beam is a direction non-parallel to the beam pathway.

A thirty-fourth aspect includes the method of any of the twenty-seventh through thirty-third aspects, wherein the scatter recess is offset from the open aperture along an entry face of the aperture body by an offset distance; and the offset distance is greater than or equal to a spatial separation distance between the target beam portion of the ion beam and the secondary beam portion of the ion beam at the entry face.

A thirty-fifth aspect includes the method of any of the twenty-seventh through thirty-fourth aspects, wherein accelerating ions from the ion source to form the ion beam comprises providing the ions with energies greater than 100V.

According to a thirty-sixth aspect of the present disclosure, an ion production system includes an ion source configured to produce ions; a collection target comprising a carbon material; an extraction electrode positioned between the ion source and the collection target and configured to accelerate ion toward the collection target thereby forming an ion beam along a beam pathway; a mass resolving aperture comprising an open aperture, wherein at least a portion of the mass resolving aperture comprises a carbon material; and a magnetic analyzer positioned along the beam pathway between the extraction electrode and the mass resolving aperture, wherein the magnetic analyzer is configured to apply a magnetic field to the ion beam thereby spatially separating a target beam portion and a secondary beam portion of the ion beam.

A thirty-seventh aspect includes the ion production system of the thirty-sixth aspect, wherein the carbon material of the collection target comprises a lattice of carbon fibers and the at least a portion of the mass resolving aperture comprising a carbon material comprises graphite.

A thirty-eighth aspect includes the ion production system of the thirty-sixth or thirty-seventh aspect, wherein the mass resolving aperture comprises an aperture body and a carbon outer layer.

A thirty-ninth aspect includes the ion production system of the thirty-sixth through thirty-eighth aspects, wherein the mass resolving aperture comprises a monolith of carbon material.

A fortieth aspect includes the ion production system of the thirty-sixth through thirty-ninth aspects, wherein the mass resolving aperture comprises an aperture body and a carbon insert removably positioned in the open aperture.

A forty-first aspect includes the ion production system of the fortieth aspect, wherein the aperture body comprises a refractory metal.

A forty-second aspect includes the ion production system of the fortieth or forty-first aspect, wherein the mass resolving aperture comprises an aperture body and an open aperture extending through the aperture body from an entry side to an exit side; the exit side of the aperture body comprises an exit face and a capture face; the open aperture extends through the aperture body from the entry side to the exit face of the exit side; the aperture body comprises a protrusion wall extending from the exit face to the capture face; the carbon insert comprises a band portion with an insert opening and a barrier portion extending from the band portion; and when the band portion is positioned in the open aperture, the barrier portion extends along the protrusion wall.

According to a forty-third aspect of the present disclosure, a method includes accelerating ions from an ion source to form an ion beam using an extraction electrode positioned between the ion source and a mass resolving aperture comprising an open aperture, wherein the ion beam propagates along a beam pathway toward a collection target; applying a magnetic field to the ion beam using a magnetic analyzer positioned along the beam pathway between the extraction electrode and the mass resolving aperture thereby spatially separating a target beam portion and a secondary beam portion of the ion beam; obstructing the secondary beam portion using the mass resolving aperture, wherein at least a portion of the mass resolving aperture comprises a carbon material; and collecting ions of the target beam portion on the collection target, wherein the collection target comprises a carbon material.

A forty-fourth aspect includes the method of the forty-third aspect, further including burning the collection target to obtain a residue comprising the ions of the target beam portion.

A forty-fifth aspect includes the method of the forty-third aspect or forty-fourth aspects, wherein a portion the ion beam impinges the mass resolving aperture, removing carbon material of the mass resolving aperture such that removed carbon material of the mass resolving aperture is collected by the collection target together with the ions of the target beam portion.

A forty-sixth aspect includes the method of the forty-fifth aspect, further including burning the collection target and the removed carbon material collected thereon to obtain a residue comprising the ions of the target beam portion.

A forty-seventh aspect includes the method of any of the forty-third through forty-sixth aspects, wherein the collection target comprises a lattice of carbon fibers and collecting the target beam portion of the ion beam comprises decelerating ions of the target beam portion by deflecting the ions off a plurality of the carbon fibers of lattice of carbon fibers.

A forty-eighth aspect includes the method of any of the forty-third through forty-seventh aspects, wherein the carbon material of the collection target comprises a lattice of carbon fibers and the at least a portion of the mass resolving aperture comprising a carbon material comprises graphite.

A forty-ninth aspect includes the method of any of the forty-third through forty-eighth aspects, wherein the mass resolving aperture comprises a carbon outer layer.

A fiftieth aspect includes the method of any of the forty-third through forty-ninth aspects, wherein the mass resolving aperture comprises a monolith of carbon material.

A fifty-first aspect includes the method of any of the forty-third through fiftieth aspects, wherein the mass resolving aperture comprises a carbon insert removably positioned in the open aperture.

A fifty-second aspect includes the method of the fifty-first aspect, wherein the mass resolving aperture comprises an aperture body and an open aperture extending through the aperture body from an entry side to an exit side; the exit side of the aperture body comprises an exit face and a capture face; the open aperture extends through the aperture body from the entry side to the exit face of the exit side; the aperture body comprises a protrusion wall extending from the exit face to the capture face; the carbon insert comprises a band portion with an insert opening and a barrier portion extending from the band portion; and when the band portion is positioned in the open aperture, the barrier portion extends along the protrusion wall.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts an ion production system, according to one or more embodiments shown and described herein;

FIG. 2 schematically depicts a front view of a mass resolving aperture including a scatter recess, according to one or more embodiments shown and described herein;

FIG. 3 schematically depicts a side view of the mass resolving aperture of FIG. 2, according to one or more embodiments shown and described herein;

FIG. 4 schematically depicts another side view of the mass resolving aperture of FIG. 2, according to one or more embodiments shown and described herein;

FIG. 5 schematically depicts a rear view of the mass resolving aperture of FIG. 2, according to one or more embodiments shown and described herein;

FIG. 6 schematically depicts a front view of an embodiment of a mass resolving aperture without a scatter recess, according to one or more embodiments shown and described herein;

FIG. 7 schematically depicts a front view of an embodiment of a mass resolving aperture comprising multiple scatter recesses, according to one or more embodiments shown and described herein;

FIG. 8 schematically depicts a side view of the mass resolving aperture of FIG. 7, according to one or more embodiments shown and described herein;

FIG. 9 schematically depicts a collection target and voltage source of the ion production system in an embodiment involving a positive ion beam, according to one or more embodiments shown and described herein;

FIG. 10 schematically depicts a collection target and voltage source of the ion production system in an embodiment involving a negative ion beam, according to one or more embodiments shown and described herein;

FIG. 11 schematically depicts an exploded view of an embodiment of the collection target of an ion production system, according to one or more embodiments shown and described herein; and

FIG. 12 schematically depicts a perspective view of a fibrous lattice of a collection target of an ion production system, according to one or more embodiments shown and described herein.

### DETAILED DESCRIPTION

Referring generally to the figures, embodiments of the present disclosure are directed to a mass resolving aperture for use in a system that uses an ion beam, such as an ion production system. The mass resolving aperture is positioned and configured to allow passage of a target beam portion of an ion beam (e.g., a portion that includes a target isotope) while obstructing a secondary beam portion of the ion beam (e.g., a portion that includes one or more secondary isotopes). The mass resolving aperture may be incorporated into a heavy metal ion production system configured to perform high-efficiency collection of ions (e.g., heavy metal ions such as ytterbium ions including ytterbium-176 ions) at a collection target of the ion production system, such that the ions are reconstituted as a material which can then be collected, stored, transported, used, etc. for various applications (e.g., a material having a high concentration of ytterbium-176 or other target isotope). By implementing the mass resolving aperture of the present disclosure in an ion production system, target isotopes may be collected at high levels of purity. Embodiments of the mass resolving aperture, ion collection system and uses thereof will now be described and, whenever possible, the same reference numerals will be used throughout the drawings to refer to the same or like parts.

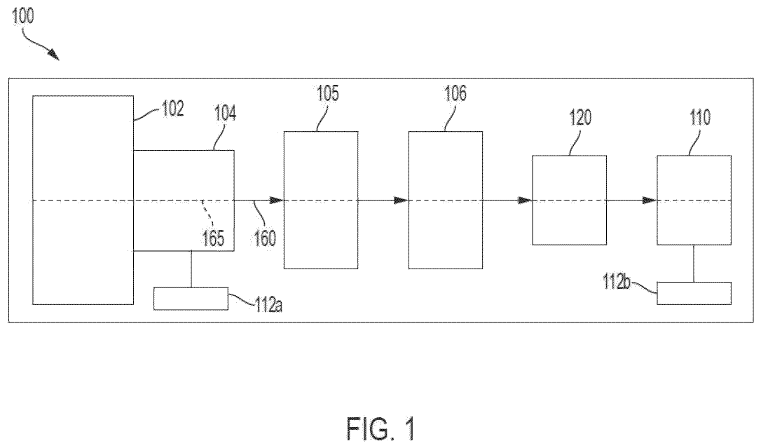

Referring now to FIG. 1, a block diagram of an ion production system 100 is shown, according to an illustrative embodiment. The ion production system 100 may include an ion source 102, one or more extraction electrodes 104, one or more beam shaping elements 105, a magnetic analyzer 106, a mass resolving aperture 120, a collection target 110. The ion source 102, the one or more extraction electrodes 104, the one or more beam shaping elements 105, the magnetic analyzer 106, the mass resolving aperture 120, and the collection target 110 are arranged sequentially such that ions are generated at the ion source 102 and sequentially pass the one or more extraction electrodes 104, the one or more beam shaping elements 105, magnetic analyzer 106, and the mass resolving aperture 120 along a beam pathway 165 before reaching the collection target 110. The ion production system 100 provides an example system that forms an ion beam to illustrate the structure and use of the mass resolving aperture 120 which, as described in more detail below, facilitates isolation of a desired portion of the ion beam 160. However, it should be understood that the mass resolving aperture 120 may be used in a variety of ion beam systems, including but not limited to the ion production system 100.

The ion source 102 is configured to produce ions. The ion source 102 may be configured as a Bernas or Freeman ion source, which includes a filament operable to emit electrons which ionize a gas provided into the ion source 102, for example a heavy metal gas such as a ytterbium vapor or a gadolinium vapor. Other metals (Lu, Tc, etc. may also be used). Interactions between the electrons and the gas ionize the gas to produce ions. In some embodiments, the ion source 102 produces positive ions (i.e., “cations,” ions having a positive polarity). In other embodiments, the ion source 102 produces negative ions (i.e., “anions,” ions having a negative polarity). While the examples of the present disclosure refer to ion sources and ion beams, it should be understood other charged particle sources are contemplated and applicable, such as a plasma source configured to generate a plasma beam. The ion source 102 includes an outlet slit or aperture so that the ions or other charged particles can be extracted from the ion source 102. In some embodiments, the ion source 102 includes auxiliary heaters to protect elements of the ion source 102 and to improve uniformity of the ions for extraction from the ion source 102.

Referring still to FIG. 1, the one or more extraction electrodes 104 may include one or more electrodes to accelerate the ion beam 160, decelerate the ion beam 160, shape the ion beam 160, aim the ion beam 160, etc. By providing an electric field that accelerates the ion beam 160 out of the ion source 102, the one or more extraction electrodes 104 provide the ion beam 160 with an extraction energy of the same or similar magnitude as a voltage of the one or more extraction electrodes 104. In some embodiments, accelerating ions from the ion source 102 to form the ion beam 160 comprises providing the ions with energies greater than 100 V. A first voltage source 112A is connected to the one or more extraction electrodes 104 and a second voltage source 112B is connected to the collection target 110. The first voltage source 112A operates as an extraction power supply such that, in operation, the ion source 102 and the one or more extraction electrodes 104 form and accelerate the ion beam 160 along the beam pathway 165, such that the ion beam 160 propagates along the beam pathway 165 toward the collection target 110. As described in more detail below, the second voltage source 112B operates as a reverse bias power supply to decelerate the ion beam 160 to thermal energies and such that particles (e.g., target isotopes) of the ion beam 160 collect on the collection target 110 in a film like manner.

In the example of FIG. 1, the ion beam 160 passes from the one or more extraction electrodes 104 to the one or more beam shaping element 105 and the magnetic analyzer 106. The one or more beam shaping elements 105 are optional and may include, for example, Einzel lens, quadrupole focusing elements, or the like. The one or more beam shaping elements 105 may be positioned between the ion source 102 and the magnetic analyzer 106 or between the magnetic analyzer 106 and the mass resolving aperture 120. The magnetic analyzer 106 is configured to provide a magnetic field that applies magnetic forces on the ion beam 160. For example, in embodiments in which the ion beam 160 comprises an ion beam, the magnetic force on each ion may be approximately equal, but the ion beam 160 may include ions of different isotopes, such that the masses of the ions vary. The magnetic force provided by the magnetic analyzer 106 may result in a separation of ions by mass. Thus, after passing through the magnetic analyzer 106, different areas of a transverse cross-section of the ion beam 160 may include different isotopes, i.e., ions of different mass. In other words, the magnetic field spatially separates the different isotopes in a direction non-parallel to a propagation direction of the ion beam 160. It should be understood that other techniques for spatially separating the ion beam 160 are contemplated that do not use the magnetic analyzer 106.

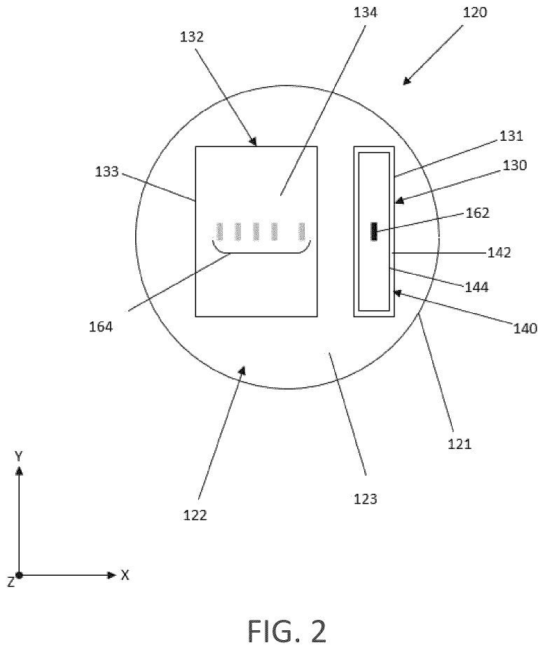

The ion beam 160 may comprise a plurality of isotopes of one or more ions. In some embodiments, only some of these isotopes are desired for capture at the collection target 110. As used herein, such isotopes are referred to as target isotopes. The another, non-target isotopes of the ion beam are referred to herein as secondary isotopes. Some example ion beams 160, target isotopes, and secondary isotopes are described in more detail below, but it should be understood that the embodiments described herein may include ion beams of all stable and radioactive isotopes. For example, the ion beam 160 may comprise ions of ytterbium (Yb) isotopes, such as ¹⁶⁸Yb, ¹⁷⁰Yb, ¹⁷¹Yb, ¹⁷²Yb, ¹⁷³Yb, ¹⁷⁴Yb, and ¹⁷⁶Yb. In some embodiments, when the ion beam 160 comprises Yb ions, a target beam portion 162 (FIG. 2) of the ion beam 160 comprises ¹⁷⁶Yb isotopes (e.g., the target isotope) and a secondary beam portion 164 (FIG. 2) of the ion beam 160 comprises one of more of ¹⁶⁸Yb, ¹⁷⁰Yb, ¹⁷¹Yb, ¹⁷²Yb, ¹⁷³Yb, and ¹⁷⁴Yb (e.g., the secondary isotopes). ¹⁷⁶Yb may be used in the production of lutetium-177 (¹⁷⁷Lu). ¹⁷⁷Lu is a theranostic radionuclide useful for both diagnostic testing and therapeutic treatments. Specifically, during decay ¹⁷⁷Lu emits a low energy beta particle that is suitable for treating cancer, including neuro endocrine tumors, prostate, breast, renal, pancreatic, and other cancers. ¹⁷⁷Lu also emits two gamma rays that can be used for diagnostic testing.

As another example, the ion beam 160 may comprise ions of gadolinium (Gd) isotopes, such as ¹⁵²Gd, ¹⁵⁴Gd, ¹⁵⁵Gd, ¹⁵⁶Gd, ¹⁵⁷Gd, ¹⁵⁸Gd, and ¹⁶⁰Gd. In some embodiments, when the ion beam 160 comprises Gd ions, the target beam portion 162 of the ion beam 160 comprises ¹⁵²Gd isotopes (e.g., the target isotope) and the secondary beam portion 164 of the ion beam 160 comprises one of more of ¹⁵⁴Gd, ¹⁵⁵Gd, ¹⁵⁶Gd, ¹⁵⁷Gd, ¹⁵⁸Gd, and ¹⁶⁰Gd (e.g., the secondary isotopes). ¹⁵²Gd may be used in the production of terbium-149 (¹⁴⁹Tb) and ¹⁵²Tb. ¹⁴⁹Tb is a radionuclide useful for both diagnostic testing, for example positron emission tomography (PET) and therapeutic treatments, such as targeted alpha-particle therapy (TAT). ¹⁵²Tb is a radionuclide useful for diagnostic testing, for example PET testing. In other embodiments, when the ion beam 160 comprises Gd ions, the target beam portion 162 comprises ¹⁵⁵Gd isotopes (e.g., the target isotope) and the secondary beam portion 164 of the ion beam 160 comprises one of more of ¹⁵²Gd, ¹⁵⁴Gd, ¹⁵⁶Gd, ¹⁵⁷Gd, ¹⁵⁸Gd, and ¹⁶⁰Gd (e.g., the secondary isotopes). ¹⁵⁵Gd may be used in the production of ¹⁵⁵Tb. ¹⁵⁵Tb is a radionuclide useful for diagnostic testing, for example single photon emission computed tomography (SPECT). In yet other embodiments, when the ion beam 160 comprises Gd ions, the target beam portion 162 comprises ¹⁶⁰Gd isotopes (e.g., the target isotope) and the secondary beam portion 164 comprises one of more of ¹⁵²Gd, ¹⁵⁴Gd, ¹⁵⁵Gd, ¹⁵⁶Gd, ¹⁵⁷Gd, and ¹⁵⁸Gd (e.g., the secondary isotopes). ¹⁶⁰Gd may be used in the production of ¹⁶¹Tb. ¹⁶¹Tb is a radionuclide useful for therapeutic treatments, such as targeted beta-particle therapy. As yet another example, the ion beam 160 may comprise ions of tellurium (Te) isotopes, such as ¹²⁰Te, ¹²²Te, ¹²³Te, ¹²⁴Te, ¹²⁵Te, ¹²⁶Te, ¹²⁸Te, and ¹³⁰Te. In some embodiments, when the ion beam 160 comprises Te ions, the target beam portion 162 of the ion beam 160 comprises ¹²⁴Te isotopes (e.g., the target isotope) and the secondary beam portion 164 of the ion beam 160 comprises one of more of ¹²⁰Te, ¹²²Te, ¹²³Te, ¹²⁵Te, ¹²⁶Te, ¹²⁸Te, and ¹³⁰Te (e.g., the secondary isotopes). ¹²⁴Te may be used in the production of both iondine-123 (¹²³I) and ¹²⁴I. ¹²³I is a radionuclide useful for diagnostic testing, for example PET testing.

Referring still to FIG. 1, the portion of the ion beam 160 that passes through the mass resolving aperture 120 (e.g., the target beam portion 162, shown in FIG. 2) is incident on the collection target 110, which is configured to receive and collect the particles of the ion beam 160. The collection target 110 can include a substrate material suitable for receiving and retaining the particles, including as a film on a surface of the collection target 110 and/or embedded in the collection target 110. The collection target 110 may comprise a carbon fiber material, such as a carbon fiber cloth, a fibrous lattice, such as a carbon fiber lattice (e.g., graphite fibers), or the like. In some embodiments, the collection target 110 comprises a crystal structure.

The collection target 110 is capable of being held at a substantially constant voltage as particles are collected on, implanted in, or otherwise received at the collection target 110. The collection target 110 is coupled to the second voltage source 112B, which can hold the collection target 110 at a target voltage. The target voltage is positive in scenarios where positive particles are generated by the ion source 102 and the target voltage is negative in scenarios where negative particles are generated by the ion source 102. Thus, the collection target 110 slows the ion beam 160 as the ion beam 160 approaches the collection target 110. The second voltage source 112B (e.g., the reverse bias power supply) operates at a lower voltage than the first voltage source 112A (e.g., the extraction power supply) such that the target voltage is less than the extraction energy of the ion beam 160. Thus, the ion beam 160 is able to reach the collection target 110 without being forced in the opposite direction by the target voltage, while being high enough to reduce the energy of ion beam 160 to minimize both electronic and nuclear stopping of the ion beam 160 at the collection target 110 (thereby minimizing scattering or sputtering that would otherwise be caused by high-energy collisions between the particles and the collection target 110), for example, to zero, or near zero levels. By reducing these interactions via the potential of the collection target 110, the particles are caused to stick and form as a film at the collection target 110 rather than colliding with the target at high energies and sputtering or scattering away.

Moreover, because the mass resolving aperture 120 blocks the secondary beam portion 164, nearly all of the particles collected by the collection target 110 comprise the one or more target isotopes. The efficiency of the ion production system 100 is thereby improved by providing collection of a high percentage of the desirable particles created by the ion source 102. Moreover, the mass resolving aperture 120 described herein increases the percentage of target isotopes that reach the collection target 110 as a percentage of total isotopes that reach the collection target 110, increasing the purity of the resultant ionic material harvested from the collection target 110, such as increased purity ¹⁷⁶Yb, ¹⁵²Gd, ¹⁵⁵Gd, or ¹⁶⁰Gd.

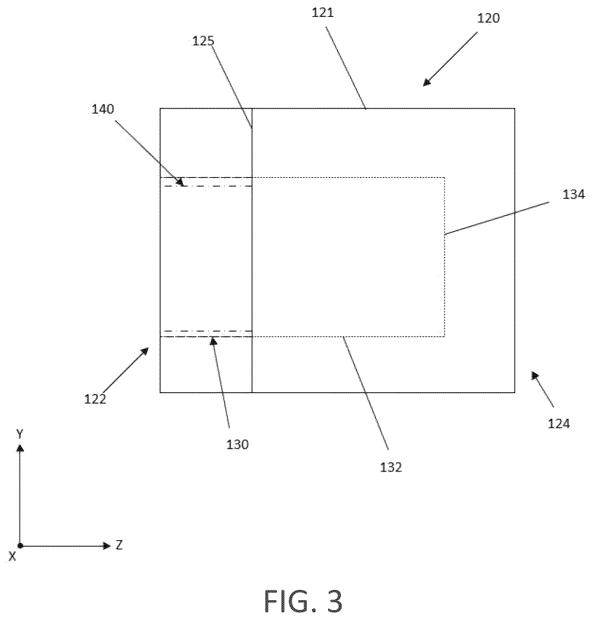

Referring now to FIGS. 2-5, the mass resolving aperture 120 is schematically depicted in more detail. With additional reference to FIG. 1, in operation, the ion beam 160 passes from the magnetic analyzer 106 to the mass resolving aperture 120, which blocks an undesired subset of the particles (i.e., the secondary beam portion 164 comprising the one or more secondary isotopes) from passing through the mass resolving aperture 120, while allowing desired particles (i.e., the target beam portion 162 comprising the one or more target isotopes) to pass through the mass resolving aperture 120. This is achieved by positioning the mass resolving aperture 120 relative to the magnetic analyzer 106 to take advantage of the separation of isotopes by mass achieved by the magnetic analyzer 106. Thus, by including the magnetic analyzer 106 and the mass resolving aperture 120, the ion beam 160 that reaches the collection target 110 includes a high percentage of a target isotope(s), with a low percentage of contamination by ions of different isotopes (i.e., secondary isotopes).

As depicted in FIGS. 2-5, the mass resolving aperture 120 comprises an aperture body 121 comprising an entry side 122, an exit side 124, and an open aperture 130 extending through the aperture body 121 from the entry side 122 to the exit side 124. The open aperture 130 comprises an entry opening 131 at an entry face 123 of the aperture body 121. The mass resolving aperture 120 also includes a scatter recess 132 extending into the entry side 122 of the aperture body 121 and terminating at a recess floor 134 positioned between the entry side 122 and the exit side 124. The scatter recess 132 includes a recess opening 133 at the entry face 123 of the entry side 122 of the aperture body 121. In operation, the open aperture 130 provides a pathway for the target beam portion 162 to pass through the mass resolving aperture 120 and reach the collection target 110 while the scatter recesses 132 and the recess floor 134 may be aligned with the secondary beam portion 164 to prevent the secondary beam portion 164 from reaching the collection target 110. That is, the aperture body 121, including the scatter recess 132, obstructs the secondary beam portion 164. Thus, the mass resolving aperture 120, minimizes the transmission of secondary isotopes through the mass resolving aperture 120 and onto the collection target 110 and maximizes transmission of one or more target isotopes through the mass resolving aperture 120 and onto the collection target 110. This improves the efficiency of the ion production system 100 and the purity of the target isotopes captured by the collection target 110.

The scatter recess 132 further minimizes the transmission of the secondary isotopes through the mass resolving aperture 120 by minimizing deflection of secondary isotopes from the aperture body 121 into the path of the target beam portion 162. The secondary beam portion 164 enters the scatter recess 132 and when the secondary beam portion 164 reaches the recess floor 134, or even a wall of the scatter recess 132, the line of sight between most or all of the secondary beam portion 164 and the target beam portion 162 (which remains aligned with the open aperture 130) is obstructed, such that minimal amount of the deflecting secondary beam portion 164 reaches the pathway of the target beam portion 162 and propagates through the open aperture 130 together with target beam portion 162. This further reduces the amount of the secondary beam portion 164 that reaches and is captured by the collection target 110, further improving the efficiency of the ion production system 100 and the purity of the target isotopes captured by the collection target 110.

In some embodiments, the recess opening 133 comprises a larger cross-sectional area than the entry opening 131 as the target beam portion 162 because, for example, after spatial separation of the ion beam 160 by the magnetic analyzer 106, the secondary beam portion 164 collectively comprises a larger cross-sectional area than the target beam portion 162. In some embodiments, one or both of the recess opening 133 and the entry opening 131 are adjustable, allowing the cross-sectional area of each to be tuned for a particular operation (e.g., for different ion beams and target isotopes). As depicted in FIGS. 2-5, the scatter recess 132 is offset from the open aperture 130 along the entry face 123 of the aperture body 121 by an offset distance that is greater than or equal to a spatial separation distance between the target beam portion 162 and the secondary beam portion 164 at the entry face 123 (or more generally, along the X-Y plane).

The open aperture 130 may be shaped and oriented to correspond with the cross-sectional shape of the target beam portion 162. For example, in some embodiments the cross-sectional shape of the target beam portion 162 is rectangular. In such embodiments, the open aperture 130 may also be rectangular, as shown in FIGS. 2-5. In other embodiments, the cross-sectional shape of the target beam portion 162 is elliptical or circular. In such embodiments, the cross-sectional shape of the open aperture 130 may be similarly elliptical or circular. Moreover, the mass resolving aperture 120 may be oriented on beam pathway 165 such that the maximum cross-sectional dimension of the open aperture 130 is aligned with the maximum cross-sectional dimension of the target beam portion 162.

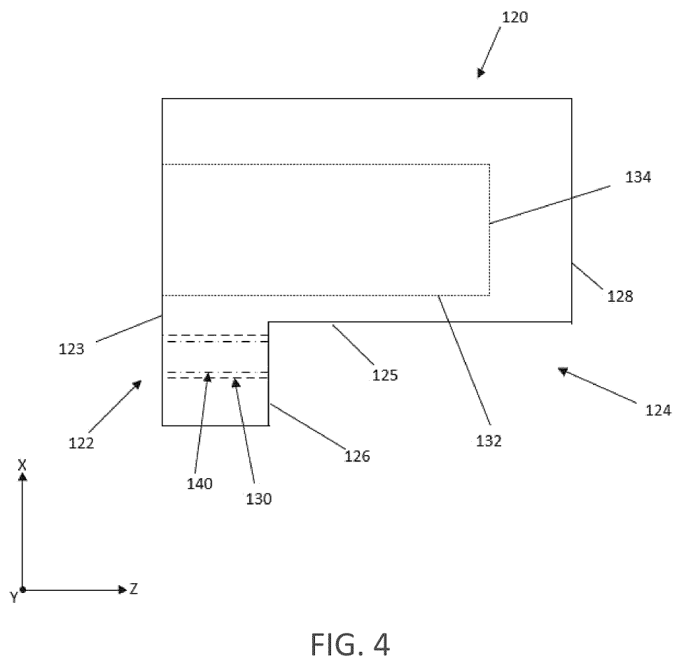

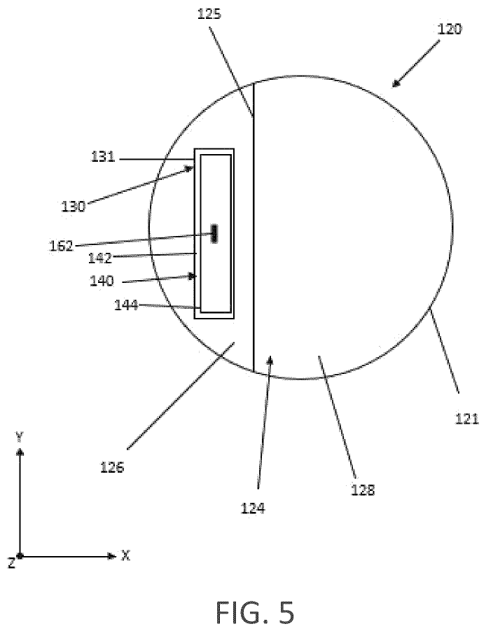

Referring now to FIGS. 4 and 5, the exit side 124 of the aperture body 121 includes an exit face 126 and a capture face 128. The open aperture 130 extends through the aperture body 121 from the entry side 122 to the exit face 126 of the exit side 124. In some embodiments, as shown in FIG. 4, the exit face 126 is closer to the entry side 122 of the aperture body 121, along a beam propagation direction, than the capture face 128. Indeed, in some embodiments, the exit face 126 is closer to the entry side 122 of the aperture body 121, along a beam propagation direction, than the recess floor 134 of the scatter recess 132. In other words, the distance from the entry face 123 to the exit face 126 is less than the distance from the entry face 123 to the capture face 128 along the beam propagation distance. Thus, the distance in which the target beam portion 162 is within the open aperture 130 is minimized while the scatter recess 132 is deep enough to prevent or substantially reduce deflection of the secondary beam portion 164 back into the path of the target beam portion 162.

As shown in FIGS. 4 and 5, the aperture body 121 includes a protrusion wall 125 extending from the exit face 126 to the capture face 128. The protrusion wall 125 extends along a protrusion plane, wherein, at the entry side 122, the protrusion plane is located between the open aperture 130 and the scatter recess 132. Increasing the distance from the entry face 123 to the capture face 128 along the beam propagation distance facilitates a deeper scatter recess 132 to minimize deflection of the secondary beam portion 164 back into the path of the target beam portion 162. However, decreasing the distance from the entry face 123 to the capture face 128 along the beam propagation direction may reduce or prevent contact between the target beam portion 162 and the mass resolving aperture 120, such as the protrusion wall 125 of the mass resolving aperture 120, as the target beam portion 162 diverges upon or after exiting the open aperture 130. Without intending to be limited by theory, such divergence may be induced by space charge. Thus, the distance from the entry face 123 to the capture face 128 may be tuned to reduce secondary isotope contamination and minimize contact between the target beam portion 162 and the mass resolving aperture 120. As described below, the effects of contact between the target beam portion 162 and the mass resolving aperture 120 may be further mitigated when at least a portion of the mass resolving aperture 120 comprises a carbon material.

Referring again to FIGS. 2-5, in some embodiments, at least a portion of the mass resolving aperture 120 comprises a carbon material, such as graphite. For example, in some embodiments, the mass resolving aperture 120 includes a carbon insert 140 positioned in the open aperture 130. The carbon insert 140 may be removably positioned within the open aperture 130 or rigidly affixed within the open aperture 130. The carbon insert 140 comprises a band portion 142 and an insert opening 144.v In some embodiments, the carbon insert 140 further comprises a barrier portion extending from the band portion 142. The barrier portion is designed such that, when the band portion 142 is positioned in the open aperture 130, the barrier portion extends along the protrusion wall 125. In some embodiments, a carbon material may be disposed along the protrusion wall independent of the carbon insert 140. In other embodiments, the mass resolving aperture 120 may include a carbon outer layer surrounding some or all of the aperture body 121. In some embodiments, the aperture body 121 comprises a refractory metal material, such as tungsten, molybdenum, or tantalum, for example, in embodiments comprising the carbon insert 140 and embodiments comprising a carbon outer layer that surrounds some or all of the aperture body 121. Alternatively, the mass resolving aperture 120 itself may comprise a monolith of carbon material, that is, the aperture body 121 may be a monolith of carbon material.

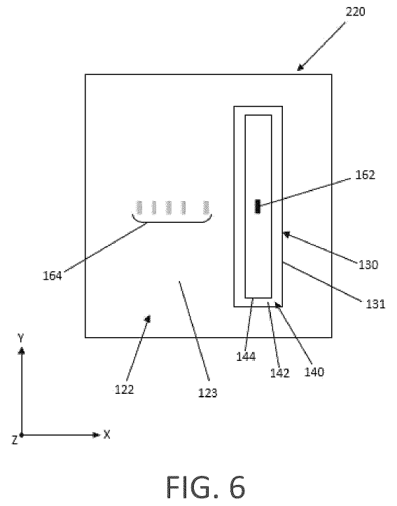

Referring now to FIG. 6, a mass resolving aperture 220 is depicted to illustrate an embodiment without the scatter recess 132 in which at least a portion of the mass resolving aperture 220 comprises a carbon material. For example, the mass resolving aperture 220 includes the carbon insert 140 positioned in the open aperture 130. In operation of any of the embodiments of FIGS. 2-6, if a portion of the ion beam 160 impinges the mass resolving aperture 120, 220 the ion beam 160 may remove material from the mass resolving aperture 120 and this removed material may be directed by the ion beam 160 to the collection target 110. The collection target 110 comprises a carbon material, thus, by including a carbon material as part of the mass resolving aperture 120, any carbon material removed from the mass resolving aperture 120 by the ion beam 160 does not contaminate the captured ions, as the carbon material of both the mass resolving aperture 120, 220 and the collection target 110 may be separated from the captured ions by burning, as described in more detail below. Indeed, removed material of the mass resolving aperture 120 may be collected by the collection target 110 together with the ions of the target beam portion.

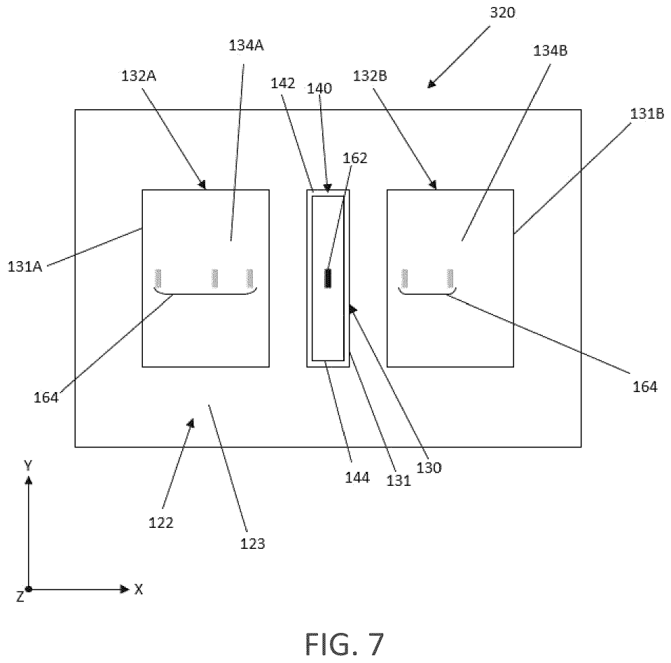

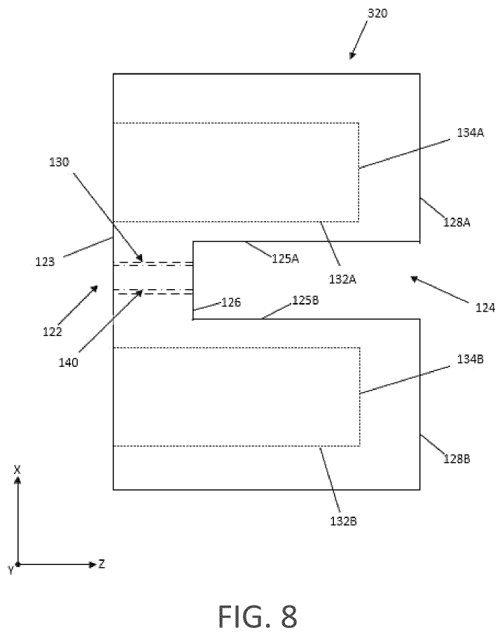

Referring now to. FIGS. 7 and 8, a mass resolving aperture 330 is depicted that includes multiple scatter recesses 132A, 132B, such as a first scatter recess 132A and a second scatter recess 132B. The first scatter recess 132A extends into the aperture body 121 toward a first capture face 128A and terminates at a first recess floor 134A. The second scatter recess 132B extends into the aperture body 121 toward a second capture face 128B and terminates at a second recess floor 134B. The mass resolving aperture 320 further comprises a first protrusion wall 125A extending from the exit face 126 to the first capture face 128A and a second protrusion wall 125B extending from the exit face 126 to the second capture face 128B. As shown in FIGS. 7 and 8, the open aperture 130 may be positioned between the first scatter recess 132A and the second scatter recess 132B. The embodiments of FIGS. 6 and 7 may be useful during an ion collection operation in which the target isotope is positioned between one or more secondary isotopes after magnetic separation. In such operations, the first scatter recess 132A and the second scatter recess 132B may each block a part of the secondary beam portion 164. Moreover, some or all of the mass resolving aperture 330 may comprise a carbon material, including any of the contemplated embodiments described above with respect to mass resolving apertures 120, 220.

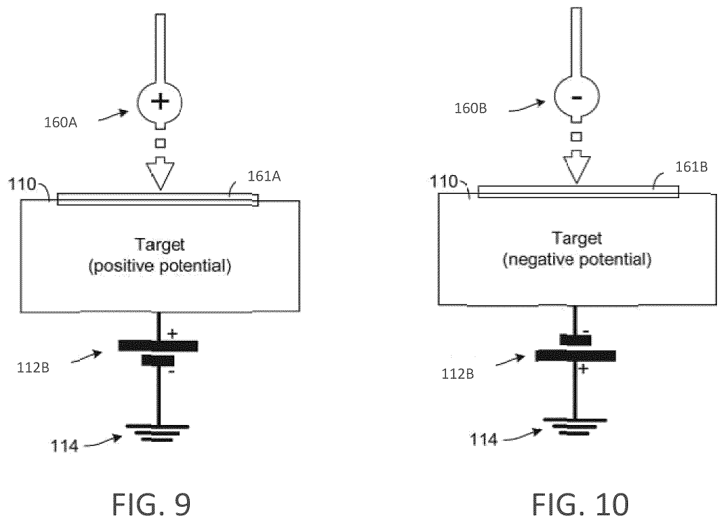

Referring now to FIG. 9, a schematic illustration of the collection target 110 and the second voltage source 112B of the ion production system 100 in an embodiment involving a positive ion beam 160A is shown, according to an example embodiment. FIG. 9 shows the positive ion beam 160A (i.e., a beam of positively charged ions) aimed towards the collection target 110 and incident on the collection target 110. Because the positive ion beam 160A has a positive polarity, the voltage of the collection target 110 is also provided with a positive polarity. FIG. 9 illustrates that the collection target 110 is connected to a positive terminal of the voltage source 112B, with the negative terminal of the voltage source 112B connected to ground 114. The voltage source 112B holds the collection target 110 at a positive potential, i.e., an electrical potential of the same polarity as the positive ion beam 160A.

The positive potential of the collection target 110 provides an electric field that resists movement of the positive ion beam 160A toward the collection target 110. The positive ion beam 160A must move across this electric field to reach the collection target 110. As it does so, kinetic energy of the positive ion beam 160A is converted into electric potential of the ions in the electric field created by the positive potential of the collection target 110. This may be thought of as being analogous to the ions rolling “uphill” to reach the collection target 110. As discussed above, the target voltage is selected and maintained such that the positive ion beam 160A reaches a low energy, for example a thermal energy, just as positive ions reach the collection target 110. Reduced to thermal energy, the positive ion beam 160A does not have extra kinetic energy that would cause it to move away from the collection target 110 or cause sputtering or scattering, and, thus, the ions of the positive ion beam 160A stick at the collection target 110, for example forming as the positive ion film 161A as shown in FIG. 9.

Referring now to FIG. 10, a schematic illustration of the collection target 110 and the second voltage source 112B of the ion production system 100 in an embodiment involving a negative ion beam 160B is shown, according to an example embodiment. FIG. 10 shows the negative ion beam 160B (i.e., a beam of negatively charged ions) aimed towards the collection target 110 and incident on the collection target 110. Because the negative ion beam 160B has a negative polarity, the voltage of the collection target 110 is also provided with a negative polarity. FIG. 10 illustrates that the collection target 110 is connected to a negative terminal of the second voltage source 112B, with the positive terminal of the voltage source 112B connected to ground 114. The second voltage source 112B holds the collection target 110 at a negative potential, i.e., an electrical potential of the same polarity as the negative ion beam 160B.

The negative potential of the collection target 110 provides an electric field which resists movement of the negative ion beam 160B toward the collection target 110. The negative ion beam 160B must move across this electric field to reach the collection target 110. As it does so, kinetic energy of the negative ion beam 160B is converted into electric potential of the ions in the electric field created by the negative potential of the collection target 110. This may be thought of as being analogous to the ions rolling “uphill” to reach the collection target 110. As discussed above, the target voltage is selected and maintained such that the negative ion beam 160B reaches a low energy, for example a thermal energy, just as negative ions reach the collection target 110. Reduced to thermal energy, the negative ion beam 160B does not have extra kinetic energy that would cause it to move away from the collection target 110 or cause sputtering or scattering, and, thus, the ions of the negative ion beam 160B stick at the collection target 110, for example forming as the negative ion film 161B shown in FIG. 10.

The ion production system 100 is thereby configured for highly efficient production and collection of ions as a constituted ionized material. By setting the collection target 110 at the target voltage as described above, a high percentage of the ions incident on the collection target 110 are caused to stick at the collection target 110, for example forming a film at the collection target 110. The efficiency of the ion production system 100 is thereby improved by providing collection of a high percentage of the desirable ions created by the ion source 102. Additionally, because material is sputtered or scattered away at a low or zero rate, it is also substantially prevented from building up on other, unwanted surfaces in the ion production system 100, thereby reducing downtime, cleaning, maintenance, etc. of the ion production system 100. Additionally, while electronic or nuclear stopping of high energy ions at the target (i.e., collisions between atoms) would cause the thermal energy of the target to increase greatly, the embodiments herein reduce the energy of the ions using the electric potential provided by the second voltage source 112B and thereby avoid the build-up of thermal energy at the target.

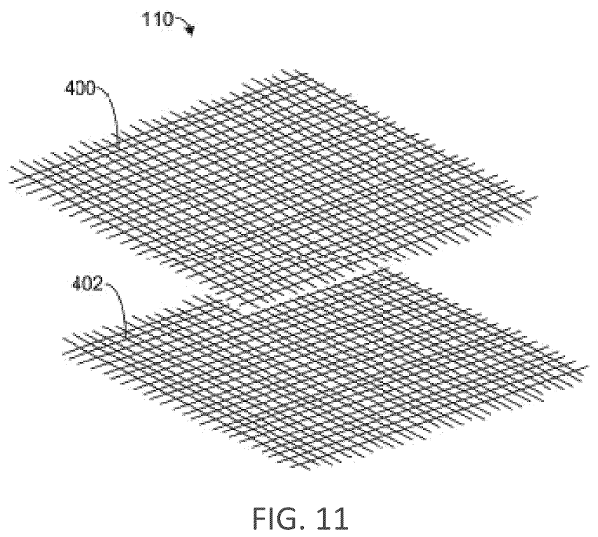

Referring now to FIG. 11, an exploded view of the collection target 110 or a portion thereof (e.g., a fibrous lattice thereof) is shown, according to some embodiments. In the example of FIG. 11, the collection target 110 includes a first lattice 400 and a second lattice 402 which form the collection target 110 as a fibrous lattice. The first lattice 400 and the second lattice 402 may be stacked as layers to form the collection target 110. In other embodiments, other numbers of lattices (layers) are included in the collection target 110 (e.g., one, three, four, five, etc.). The fibrous lattice may be formed as a carbon felt or carbon foam in various embodiments.

The first lattice 400 includes a plurality of fibers arranged in a plurality of directions, shown as two orthogonal directions. The plurality of fibers may be woven together or otherwise coupled to form the first lattice 400. The second lattice 402 also includes a plurality of fibers arranged in a plurality of directions, shown as two orthogonal directions, which are woven together or otherwise coupled to form the second lattice 402. The first lattice 400 and the second lattice 402 may be arranged relative to one another such that fibers of the first lattice 400 are parallel with fibers of the second lattice 402 or may be oriented differently so that fibers of the first lattice 400 are at non-orthogonal angles relative to fibers of the second lattice 402. In some embodiments, the first lattice 400 and the second lattice 402 appear substantially solid to the naked human eye but are made up of fibers at a microscopic or smaller level.

The fibers of the first lattice 400 and the second lattice 402 may be made of carbon, for example FIG. 11 shows a first lattice 400 of carbon fibers and a second lattice 402 of carbon fibers. In some embodiments, the fibers are made of graphite, for example such that some or all of the fibers of the first lattice 400 and the second lattice 402 are graphite fibers. The material of the fibers is preferably a high purity (e.g., greater than 95% carbon) such that, when burned (in the presence of oxygen), the carbon fibers themselves leave little or no solid residue. When in vacuum the carbon fibers are configured to handle high temperatures (e.g., greater than 200° C., greater than 300° C., greater than 800° C.) without substantially deforming, melting, etc.

The first lattice 400 and the second lattice 402 are configured to capture ions incident thereon. The arrangement of the plurality of fibers causes an ion to deflect (scatter, collide, etc.) off of multiple fibers as the kinetic energy of the ion is reduced until the ion will stay at the collection target 110 (e.g., reduce to thermal energy), without scattering away from the collection target 110 after a single collision. The arrangement of the fibers is partially porous, such that some ions are able to penetrate beyond an outer surface of the first lattice 400, thus reducing the amount of energy built up at the surface of the first lattice 400 and allowing ions to scatter multiple times without escaping the collection target 110 (e.g., vaporizing away from the collection target 110). Accordingly, relative to a flat plate or block of material, the lattice structure provides an increased surface area and overlapping geometry that can facilitate capture a high percentage of the ions incident on the collection target 110 (e.g., greater than 40%, greater than 90% in some arrangements). The first lattice 400 and the second lattice 402 thereby provide efficient collection of the desired isotope at the collection target 110.

The first lattice 400 and the second lattice 402 are also configured to burn (in the presence of oxygen) or otherwise react to leave (e.g., be reduced to) a residue that includes a high concentration of the desired isotope. For example, the fibrous lattice configuration of FIG. 11 provides the collection target 110 with an increased surface-area-to-mass ratio as compared to a solid block or plate of carbon or graphite, which enables relatively easy burning of the of the first lattice 400 and the second lattice 402 (e.g., as compared to a solid block of graphite, which typically will not burn). For example, during operation of the ion production system 100, the collection target 110 captures the desired isotope (in the first lattice 400 and the second lattice 402 in the example of FIG. 11) while the collection target 110 is held in vacuum without a substantial amount oxygen present (thereby preventing complete burning of the collection target 110). The collection target 110 can then be removed from vacuum for processing to extract the isotope from fibrous lattice. Outside vacuum, oxygen is present which allows burning of the carbon fibers. The fibrous lattice can then be burned to reduce the fibrous lattice to a residue having a high concentration of the desired isotope. The carbon dissipates as gas after burning, such that the remaining material is of the desired isotope, which may oxidize during the extraction process. For example, in some embodiments, a powder of oxidized ytterbium (e.g., oxidized ytterbium-176) is left as a powder (e.g., white-colored powered) after burning of the target. In embodiments in which a portion of the mass resolving aperture 120 (FIGS. 1-5), 220 (FIG. 6), 320 (FIGS. 7 and 8) comprises a carbon material and some of that carbon material of the mass resolving aperture 120, 220, 320 is removed by the ion beam 160, such removed carbon material does not contaminate the desired isotope as the removed carbon material burns together with the material of the collection target 110, and dissipates as a gas after burning.

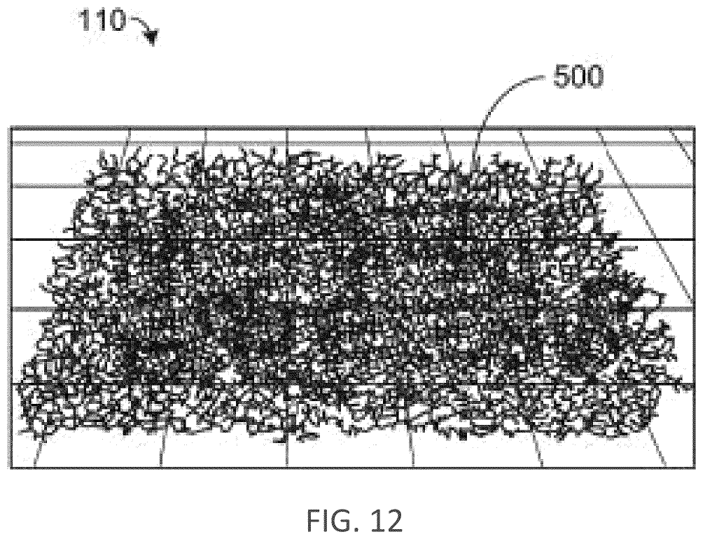

Referring now to FIG. 12, a perspective view of a fibrous lattice 500 of the collection target 110 is shown, according to some embodiments. The fibrous lattice 500 can be used as an alternative to the first lattice 400 and the second lattice 402 of FIG. 11 or may be used in combination with the first lattice 400 and/or the second lattice 402 of FIG. 11 in various embodiments. As shown in FIG. 12, the fibrous lattice 500 includes a plurality of fibers arranged in a tangled web, such that the fibrous lattice 500 may be characterized as an open-celled foam. As in the example of FIG. 12, the plurality of fibers may be carbon fibers and/or graphite fibers. The fibrous lattice 500 is configured to capture ions such that the desired isotope is collected in the fibrous lattice 500. The fibrous structure of the fibrous lattice 500 may cause ions to deflect off multiple fibers before coming to rest in the fibrous lattice 500, without scattering away from the fibrous lattice 500 after a single collision. The fibrous lattice 500 also has a high surface-area-to-mass ratio which facilitates easy burning of the fibrous lattice 500 to reduce the fibrous lattice 500 to a residue having a high concentration of the desired isotope.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical values or idealized geometric forms provided. Accordingly, these terms should be interpreted as indicating that insubstantial or inconsequential modifications or alterations of the subject matter described and claimed are considered to be within the scope of the disclosure as recited in the appended claims.

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, optical, or fluidic.

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

1-52. (canceled)

53. A mass resolving aperture comprising:
an aperture body;
an open aperture extending through the aperture body from an entry side to an exit side; and
a scatter recess extending into the entry side of the aperture body and terminating at a recess floor positioned between the entry side and the exit side.

54. The mass resolving aperture of claim 53, wherein:
the exit side of the aperture body comprises an exit face and a capture face;
the open aperture extends through the aperture body from the entry side to the exit face of the exit side; and
the exit face is closer to the entry side of the aperture body, along a beam propagation direction, than the capture face.

55. The mass resolving aperture of claim 54, wherein the exit face is closer to the entry side of the aperture body, along a beam propagation direction, than the recess floor of the scatter recess.

56. The mass resolving aperture of claim 53, wherein:
the scatter recess comprises a recess opening at an entry face of the entry side of the aperture body;
the open aperture comprises an entry opening at the entry face of the aperture body; and
the recess opening comprises a larger cross-sectional area than the entry opening.

57. The mass resolving aperture of claim 53, wherein at least a portion of the aperture body comprises a carbon material.

58. The mass resolving aperture of claim 53, further comprising a carbon insert removably positioned in the open aperture.

59. An ion production system comprising:
an ion source configured to produce ions;
a collection target;
an extraction electrode positioned between the ion source and the collection target and configured to accelerate ions, forming an ion beam along a beam pathway;
a mass resolving aperture comprising:
an aperture body;
an open aperture extending through the aperture body from an entry side to an exit side; and
a scatter recess extending into the entry side of the aperture body and terminating at a recess floor positioned between the entry side and the exit side; and
a magnetic analyzer positioned along the beam pathway between the extraction electrode and the mass resolving aperture, wherein the magnetic analyzer is configured to apply a magnetic field to the ion beam thereby spatially separating a target beam portion of the ion beam and a secondary beam portion of the ion beam.

60. The ion production system of claim 59, wherein the collection target and at least a portion of the mass resolving aperture comprise a carbon material.

61. The ion production system of claim 59, wherein the target beam portion of the ion beam comprises ytterbium-176 and the secondary beam portion of the ion beam comprises one or more other ytterbium isotopes.

62. The ion production system of claim 59, wherein the target beam portion of the ion beam comprises gadolinium-152, gadolinum-155, or gadolinum-160, and the secondary beam portion of the ion beam comprises one or more other gadolinium isotopes.

63. The ion production system of claim 59, wherein:
the exit side of the aperture body comprises an exit face and a capture face;
the open aperture extends through the aperture body from the entry side to the exit face of the exit side; and
the exit face is closer to the entry side of the aperture body, along a beam propagation direction, than the capture face.

64. The ion production system of claim 63, wherein the exit face is closer to the entry side of the aperture body, along a beam propagation direction, than the recess floor of the scatter recess.

65. The ion production system of claim 59, wherein:
the scatter recess comprises a recess opening at an entry face of the entry side of the aperture body;
the open aperture comprises an entry opening at the entry face of the aperture body; and
the recess opening comprises a larger cross-sectional area than the entry opening.

66. A method comprising:
accelerating ions from an ion source to form an ion beam using an extraction electrode positioned between the ion source and a mass resolving aperture, wherein the ion beam propagates along a beam pathway toward a collection target;
applying a magnetic field to the ion beam using a magnetic analyzer positioned along the beam pathway between the extraction electrode and the mass resolving aperture thereby spatially separating a target beam portion of the ion beam and a secondary beam portion of the ion beam; and
obstructing the secondary beam portion using the mass resolving aperture, wherein the mass resolving aperture comprises:
an aperture body;
an open aperture extending through the aperture body from an entry side to an exit side;
a scatter recess extending into the entry side of the aperture body and terminating at a recess floor positioned between the entry side and the exit side; and
wherein at least a portion of the secondary beam portion enters the scatter recess of the mass resolving aperture.

67. The method of claim 66, further comprising collecting ions of the target beam portion on the collection target after the target beam portion of the ion beam passes through the open aperture of the mass resolving aperture.

68. The method of claim 67, wherein the collection target comprises a lattice of carbon fibers and collecting the target beam portion of the ion beam comprises decelerating ions of the target beam portion by deflecting the ions off a plurality of the carbon fibers of lattice of carbon fibers.

69. The method of claim 66, wherein the collection target and at least a portion of the mass resolving aperture comprise a carbon material.

70. The method of claim 69, wherein a portion the ion beam impinges the mass resolving aperture, removing at least some of the carbon material of the mass resolving aperture such that removed carbon material of the mass resolving aperture is collected by the collection target together with the target beam portion of the ion beam.

71. The method of claim 66, wherein the magnetic field spatially separates the target beam portion and the secondary beam portion of the ion beam is a direction non-parallel to the beam pathway.

72. The method of claim 66, wherein:
the scatter recess is offset from the open aperture along an entry face of the aperture body by an offset distance; and
the offset distance is greater than or equal to a spatial separation distance between the target beam portion of the ion beam and the secondary beam portion of the ion beam at the entry face.
